(19) United States
(12) Patent Application Publication
(10) Pub. No.: US 2026/0096243 A1
(43) Pub. Date: Apr. 2, 2026

(54) PREPARATION METHOD OF ELECTRODE GRID LINES, AND PHOTOVOLTAIC (PV) CELL

(71) Applicant: BEIJING ZENITHNANO TECHNOLOGY CO., LTD., Beijing (CN)

(72) Inventors: Kaiqi PAN, Beijing (CN); Zhicong Li, Beijing (CN); Guanghang Yang, Beijing (CN); Jingjing Shu, Beijing (CN); Shudong Zhong, Beijing (CN)

(73) Assignee: BEIJING ZENITHNANO TECHNOLOGY CO., LTD., Beijing (CN)

(21) Appl. No.: 19/204,729

(22) Filed: May 12, 2025

Related U.S. Application Data
(63) Continuation-in-part of application No. PCT/CN2024/136653, filed on Dec. 4, 2024.

(30) Foreign Application Priority Data
Sep. 29, 2024 (CN) 202411372625.0
Nov. 29, 2024 (CN) 202411735427.6

(51) Int. Cl. H10F 77/20

(52) U.S. Cl. CPC H10F 77/215

(57) ABSTRACT

The provided is a preparation method of electrode grid lines, and a photovoltaic (PV) cell. The preparation method of electrode grid lines includes the following steps: S1: providing a polymer layer as a transfer substrate; S2: applying conductive paste onto a formed side of the polymer layer to at least completely fill a trench in the formed side, and removing excess conductive paste from a surface of the polymer layer; S3: providing a base material, aligning and bonding the side of the polymer layer applied with the conductive paste to the base material, and transferring the conductive paste onto the base material through a transfer method with a preset process parameter; S4: removing the polymer layer; and S5: sintering the conductive paste onto the base material, and forming electrode grid lines with a preset aspect ratio.

### CROSS-REFERENCE TO THE RELATED APPLICATIONS

This application is a continuation-in-part application of International Application No. PCT/CN2024/136653, filed on Dec. 4, 2024, which is based upon and claims priority to Chinese Patent Application No. 202411372625.0, filed on Sep. 29, 2024; and Chinese Patent Application No. 202411735427.6, filed on Nov. 29, 2024, the entire contents of which are incorporated herein by reference.

### TECHNICAL FIELD

The present disclosure relates to the technical field of photovoltaic (PV) cells, and in particular to a preparation method of electrode grid lines, and a PV cell.

### BACKGROUND

With an advancement of national carbon peaking and carbon neutrality goals, the building of a new electricity system centered on renewable energy is being accelerated, significantly elevating the status of the photovoltaic (PV) industry. Solar cells are core components of PV systems, and industrialized production dominated by monocrystalline silicon PV cells occupies a critical position, accounting for over 90% of total solar cell production. Electrode grid lines are key components of solar cells, having a significant effect on the performance of solar cells. Electrode grid lines primarily use materials with good conductive performance. Conductive paste is currently one of the most widely used materials for electrode grid lines, offering excellent conductive performance and chemical stability, making it suitable for PV cell preparation. Optimizing the preparation process of conductive paste grid lines can effectively improve the photoelectric conversion efficiency of solar cells.

The printing process of conductive paste grid lines in PV cells is one of the key production processes, and it is mainly designed to form electrodes on silicon wafers so as to collect current generated by the PV effect. Common electrode grid line printing technologies mainly include screen printing, inkjet printing, offset printing, and flexographic printing. Among them, screen printing is the most widely used technology, which prints the conductive paste onto the surface of the PV cell through a screen to form the electrode pattern, enabling electrical energy collection and conduction.

Although a screen printing is commonly used, it has certain shortcomings compared to conductive paste transfer technology. For example, conductive paste transfer technology exhibits higher resolution, more stable product quality, higher production efficiency, broader applicability, and stronger durability.

However, problems may arise in the transfer technology due to the flexibility of transfer substrate films failing to meet usage requirements. For instance, some substrate films may be too soft, causing deformation after subsequent conductive paste filling, while others may be too hard, making them brittle and unusable. Additionally, the substrates may fail to automatically separate from the base material, thereby affecting the grid line structure. However, no effective solutions have been developed to address these problems so far.

### SUMMARY

An objective of the present disclosure is to provide a preparation method of electrode grid lines, and a photovoltaic (PV) cell to address at least one of the problems in the prior art.

The present disclosure adopts the following technical solution. A preparation method of electrode grid lines includes the following steps:
S1: providing a polymer layer as a transfer substrate;
S2: applying conductive paste onto a formed side of the polymer layer to at least completely fill trenches in the formed side, and removing excess conductive paste from a surface of the polymer layer, ensuring that a surface of the trench and a surface of the conductive paste are coplanar;
S3: providing a base material, aligning and bonding the side of the polymer layer applied with the conductive paste to the base material, and transferring the conductive paste onto the base material through a transfer method with a preset process parameter, where the process parameter for transferring includes a pressure of 1-20 MPa, a temperature of 80-180° C., and a duration of 0.5-10 min;
S4: removing the polymer layer to retain the conductive paste on the base material; and
S5: sintering the conductive paste onto the base material, and forming electrode grid lines with a preset aspect ratio.

Preferably, the step S1: providing a polymer layer as a transfer substrate includes the following steps:
S101: providing a preset mold complementary in terms of shape to an electrode pattern to be embossed; and
S102: preparing a desired polymer layer on the mold according to a preset process parameter to serve as the transfer substrate.

Preferably, the step S102: preparing a desired polymer layer on the mold according to a preset process parameter to serve as the transfer substrate includes:
preparing a 15-85 μm thick polymer layer with trenches on the mold, drying the polymer layer at 100-125° C., demolding from a side of the mold, and obtaining a desired polymer layer with a micron- or nano-scale electrode pattern as the transfer substrate.

Preferably, in the step S102, the polymer layer has a thickness of 15-50 μm.

Preferably, the step S1: providing a polymer layer as a transfer substrate further includes:
S111: providing a polymer layer; and
S112: forming, by hot-embossing, the trenches for an electrode pattern on the polymer layer through a mold.

Preferably, the step S1 includes: preparing the polymer layer by an electrospinning method or a flatbed coating method.

Preferably, the step S1 includes: preparing the polymer layer by an electrospinning method as follows:
S11: dissolving a water-soluble polymer material in a preset solvent to prepare a uniform spinning solution;
S12: loading the spinning solution into a syringe, and spinning through an electrospinning device; and
S13: allowing, during spinning, a fiber to form a film on a preset device, collecting and post-treating the film, and finally obtaining a desired polymer layer.

Preferably, the step S11: dissolving a water-soluble polymer material in a preset solvent to prepare a uniform spinning solution includes:

dissolving polyvinyl pyrrolidone (PVP) and tetrabutyl titanate in a mixed solvent of ethanol and acetic acid, and preparing a precursor solution including 3-5 wt % PVP and 18-22 wt % tetrabutyl titanate.

Preferably, the step S11: dissolving a water-soluble polymer material in a preset solvent to prepare a uniform spinning solution includes:
slowly adding PVP and diphenylalanine into a mixed solvent of methanol and N,N-methylacetamide under stirring, continuously stirring until the PVP and diphenylalanine are fully dissolved, and obtaining a transparent polymer solution.

Preferably, the step S12: loading the spinning solution into a syringe, and spinning through an electrospinning device includes:
loading the prepared spinning solution into the syringe with a preset inner diameter, and performing electrospinning with a preset working voltage.

Preferably, the step S13: allowing, during spinning, a fiber to form a film on a preset device, collecting and post-treating the film, and finally obtaining a desired polymer layer includes:
allowing a polymer layer formed by spinning to deposit uniformly on a collection device, and performing a corresponding pretreatment step based on an intended use of the fiber film.

Preferably, the step S111: providing a polymer layer includes:
preparing a polymer layer with a thickness of 35-85 μm through an electrospinning method or a flatbed coating method.

Preferably, the step S112: forming, by hot-embossing, the trenches for an electrode pattern on the polymer layer through a mold includes:
placing the prepared polymer layer on the mold, and hot-embossing, by a precision hot-embossing machine, the polymer layer at 100-180° C., thereby forming a micron- or nano-scale trench structure on a surface of the polymer layer.

Preferably, the mold includes one of a monocrystalline silicon base material, a polycrystalline silicon base material, a copper base material, a nickel base material, a copper-nickel alloy base material, a nickel-iron alloy base material, an iron-aluminum alloy base material, or an aluminum alloy base material.

Preferably, a protrusion of the mold is complementary to the trench in shape; and
the mold is in the shape of one of an isosceles triangle, an isosceles trapezoid, an ellipse, a hexagon, a right-angle trapezoid, or a rectangle.

Preferably, a shape of the mold features an aspect ratio of 1 to 3.

Preferably, a surface of the mold is coated with a self-assembled monolayer (SAM).

Preferably, the SAM includes one of a silane compound, a siloxane compound, or a perfluorinated compound.

Preferably, the step S2: applying conductive paste onto a formed side of the polymer layer to completely fill a trench in the formed side, and removing excess conductive paste from a surface of the polymer layer, ensuring that a surface of the trench and a surface of the conductive paste are coplanar includes:
uniformly spreading, by a flatbed coating method, the conductive paste over the formed polymer layer such that the conductive paste completely fills the trench; and scraping off excess conductive paste to ensure complete filling and uniform and deformation-free distribution of the conductive paste.

Preferably, in the step S3, the providing a base material, and aligning and bonding the side of the polymer layer applied with the conductive paste to the base material includes:
tightly bonding, while drying the conductive paste, the conductive paste to a surface of the base material by applying uniform-codirectional pressure at a preset temperature; and
remaining, within the temperature and the pressure, a macroscopic morphology of the conductive paste transferred onto the base material unchanged;
where, the base material is selected from one of a crystalline silicon wafer base material, a glass base material, a perovskite base material, a metal base material, or a polymer base material.

Preferably, the step S4: removing the polymer layer to retain the conductive paste on the base material includes:
immersing a silicon wafer after transferring into a 25-75° C. aqueous solution, such that the polymer layer is dissolved and separated, leaving a successfully transferred conductive paste pattern, and forming a basic structure of an electrode grid line.

Preferably, the step S5: sintering the conductive paste onto the base material, and forming electrode grid lines with a preset aspect ratio includes:
placing a silicon wafer with the transferred conductive paste in a high-temperature furnace; sintering the conductive paste at 200-800° C., ensuring that the conductive paste is completely sintered and tightly bonded to the silicon wafer; and forming the electrode grid lines with a preset aspect ratio.

Preferably, the conductive paste is selected from one of silver paste, aluminum paste, copper paste, chromium paste, tin paste, indium paste, nickel paste, titanium paste, or tantalum paste; the silver paste further includes of pure silver particles, copper or nickel particles coated with silver.

Preferably, the polymer layer has a glass transition temperature of 60-120° C., and is made of a water-soluble polymer material.

Preferably, the water-soluble polymer material includes one of PVP, polyethylene glycol (PEG), polyvinyl alcohol (PVA), sodium polyacrylate (PAAS), polyvinyl alcohol-polyacrylic acid (PVA-PAA), or polyvinyl alcohol-polyacrylonitrile (PVA-PAN); and
the PVA has an average polymerization degree of 1,700 and an alcoholysis degree of 88-92%; the PVA includes ordinary PVA and modified PVA; and the modified PVA is carboxyl-modified PVA with a carboxyl modification degree of 2-8%.

Preferably, the step S102 further includes: providing a bonding layer at a side of the polymer layer away from the mold, and providing a substrate at a side of the bonding layer away from the polymer layer.

Preferably, the substrate is made of one of polyimide (PI), polyethylene terephthalate (PET), polyamide (PA), or polycarbonate (PC).

Preferably, the step S3 further includes: separating, during transferring with the preset process parameter, the bonding layer and the substrate from the polymer layer.

To achieve the above objective, another aspect of the present disclosure further provides a PV cell.

In the present disclosure, the PV cell includes prepared electrode grid lines.

The present disclosure has the following beneficial effects. In the embodiment of the present disclosure, the electrode grid lines are prepared by a transfer means, and the preparation method includes the following steps. S1. A polymer layer is provided as a transfer substrate. S2. Conductive paste is applied onto a formed side of the polymer layer to at least completely fill a trench in the formed side, and excess conductive paste is removed from a surface of the polymer layer, ensuring that a surface of the trench and a surface of the conductive paste are coplanar. S3. A base material is provided, the side of the polymer layer applied with the conductive paste is aligned and bonded to the base material, and the conductive paste is transferred onto the base material through a transfer method with a preset process parameter, where the process parameter for transferring includes a pressure of 1-20 MPa, a temperature of 80-180° C., and a duration of 0.5-10 min. S4. The polymer layer is removed to retain the conductive paste on the base material. S5. The conductive paste is sintered onto the base material, and electrode grid lines with a preset aspect ratio are formed. In this way, the present disclosure achieves the goal of preparing the electrode grid lines. The present disclosure realizes technical effects such as reduced process time, simplified workflows, and excellent flexibility and separation ease of the substrate film. The present disclosure further addresses the following problems in transfer technology. The flexibility of transfer substrate films fails to meet usage requirements. For instance, some substrate films may be too soft, causing deformation after subsequent silver paste filling, while others may be too hard, making them brittle and unusable. Additionally, the substrates may fail to automatically separate from the base material, thereby affecting the grid line structure.

### BRIEF DESCRIPTION OF THE DRAWINGS

FIG. 1 is a structural schematic flowchart of a preparation method of electrode grid lines according to the present disclosure;

FIG. 2 is another structural schematic flowchart of the preparation method of electrode grid lines according to the present disclosure;

FIG. 3 is still another structural schematic flowchart of the preparation method of electrode grid lines according to the present disclosure;

FIG. 4 is yet another structural schematic flowchart of the preparation method of electrode grid lines according to the present disclosure;

FIG. 5 is a schematic flowchart of a preparation method of electrode grid lines according to the present disclosure;

FIG. 6 is another schematic flowchart of the preparation method of electrode grid lines according to the present disclosure;

FIG. 7 is still another schematic flowchart of the preparation method of electrode grid lines according to the present disclosure;

FIG. 8 is a schematic flowchart of a polymer layer preparation method according to the present disclosure; and

FIG. 9 is a structural schematic diagram of a mold in the preparation method of electrode grid lines according to the present disclosure.

### REFERENCE NUMERALS

1. mold;
2. polymer layer;
3. trench;
4. conductive paste;
5. base material;
6. electrode grid line;
7. bonding layer; and
8. substrate.

### DETAILED DESCRIPTION OF THE EMBODIMENTS

To enable those skilled in the art to better understand the solutions of the present disclosure, the technical solutions in the embodiments of the present disclosure will be clearly and completely described below in conjunction with the drawings in the embodiments of the present disclosure. Obviously, the described embodiments are only a part of, not all of, the embodiments of the present disclosure. All other embodiments obtained by those of ordinary skill in the art based on the embodiments of the present disclosure without creative efforts should fall within the protection scope of the present disclosure.

It should be noted that the terms “first”, “second”, and so on in the description and claims of the present disclosure and in the above drawings are intended to distinguish between similar objects but do not necessarily indicate a specific order or sequence. It should be understood that the data termed in such a way is interchangeable in proper circumstances such that the embodiments of the present disclosure described herein can be implemented in other orders than the order illustrated or described herein. Moreover, the terms “include”, “contain”, and any other variants mean to cover the non-exclusive inclusion, for example, a process, method, system, product, or device that includes a list of steps or units is not necessarily limited to those steps or units which are clearly listed, but may include other steps or units which are not expressly listed or inherent to such a process, method, system, product, or device.

In addition, the meanings of the terms “mount”, “dispose”, and “connect” should be understood in a broad sense. For example, “connection” may be a fixed connection, a removable connection, or integration; may be a mechanical connection or an electrical connection; may be a direct connection or an indirect connection implemented by using an intermediate medium; or may be intercommunication between two components, elements or components. Those of ordinary skill in the art may understand specific meanings of the above terms in the present disclosure based on a specific situation.

It should be noted that the embodiments in the present disclosure and features in the embodiments may be combined with each other in a non-conflicting situation. The present disclosure will be described in detail below with reference to the drawings and embodiments.

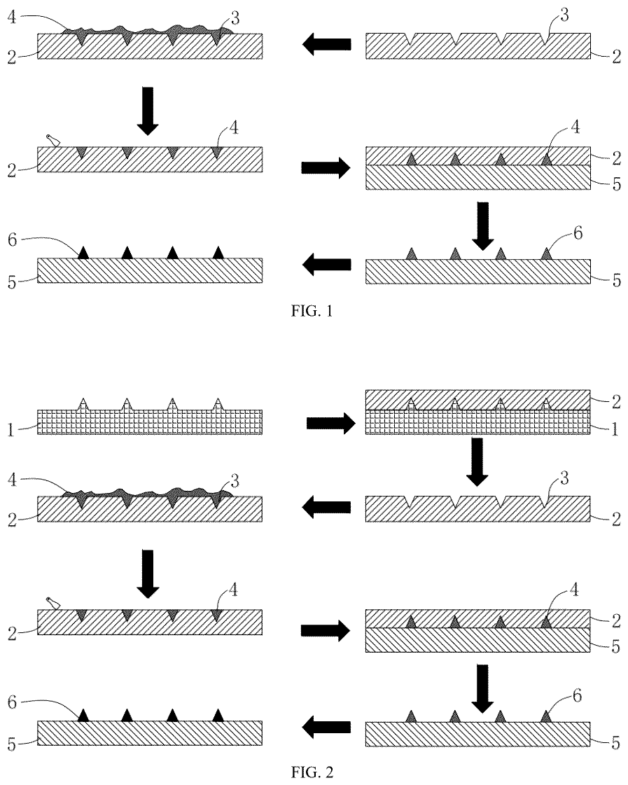

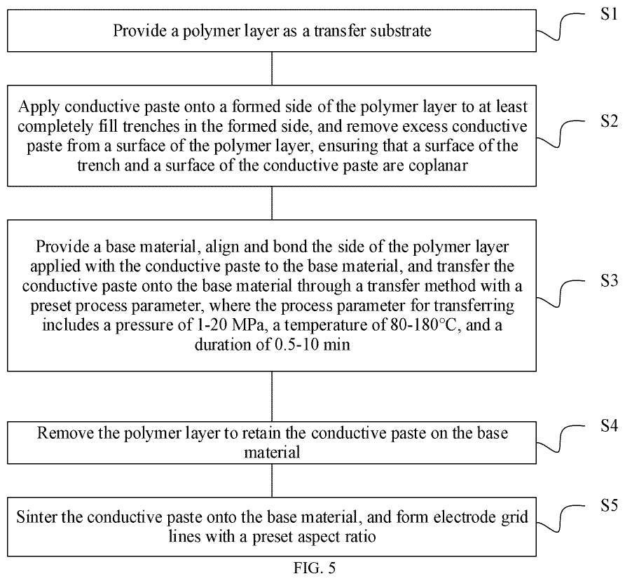

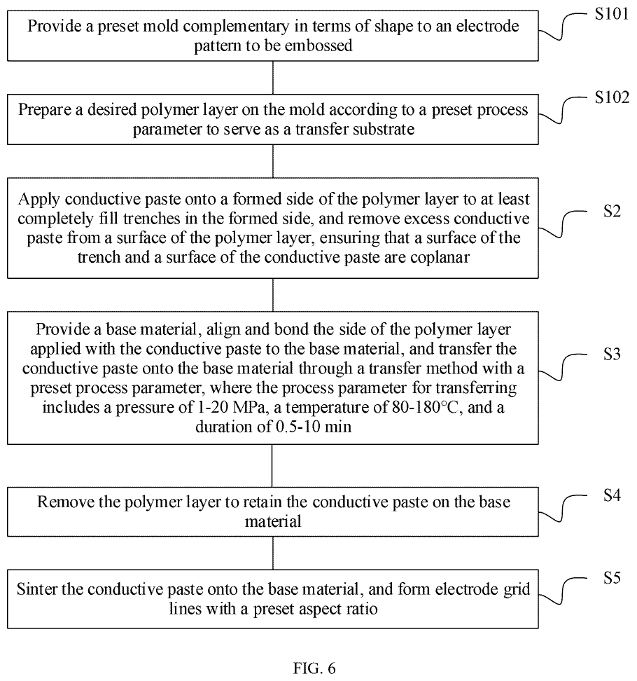

As shown in FIGS. 1 to 9, the present disclosure relates to a preparation method of electrode grid lines, and a PV cell. As shown in FIGS. 1 and 5, the preparation method of electrode grid lines includes the following steps.

S1. Polymer layer 2 is provided as a transfer substrate.

This step ensures a good transfer effect, thereby ensuring the normal execution of subsequent processes.

As shown in FIGS. 2, 3, and 6, according to an embodiment of the present disclosure, preferably, the step S1 that the polymer layer 2 is provided as a transfer substrate is performed as follows.

S101. Preset mold 1 complementary in terms of shape to an electrode pattern to be embossed is provided.

This step enables the acquisition of the desired polymer layer, ensuring subsequent processes.

It should be noted that polyvinyl pyrrolidone (PVP) is a non-ionic polymer with excellent water solubility, biocompatibility, and film-forming properties.

In the present disclosure, based on in-depth understanding of PV conductive pastes and research on the water solubility of PVP, PVP exhibits no reactivity with conductive paste binders/solvents and demonstrates weak adhesion, making it an ideal carrier for transferring conductive pastes.

As a synthetic water-soluble polymer, PVP possesses general properties of such compounds. It provides colloidal protection, film-forming property, adhesion, hygroscopicity, solubilization, or coagulation. However, its most distinctive features are excellent solubility and biocompatibility. PVP is soluble in both water and most organic solvents, with low toxicity and good biocompatibility. Few synthetic polymers, like PVP, exhibit such characteristics. Particularly in health-related fields such as pharmaceuticals, food, and cosmetics, PVP shows promising development prospects as the price of its raw material, butyrolactone, decreases.

High-molecular-weight PVP exhibits no significant adhesion or reactivity with conductive pastes, meeting requirements for PVP as a conductive paste carrier. The conductive paste can be applied onto PVP, and residual conductive paste on the surface of PVP can be completely scraped off, ensuring unchanged properties of the conductive paste in trenches.

The glass transition temperature of PVP is 80-120° C. By applying specific temperature (80-160° C.) and pressure (1-20 MPa), PVP can be transferred onto a silicon wafer, creating an easily achievable processing condition.

According to an embodiment of the present disclosure, preferably, in the step S1, the mold includes one of a monocrystalline silicon base material, a polycrystalline silicon base material, a copper base material, a nickel base material, a copper-nickel alloy base material, a nickel-iron alloy base material, an iron-aluminum alloy base material, or an aluminum alloy base material.

The availability of multiple material options ensures flexibility, making this step easy to implement.

It should be noted that the monocrystalline silicon base material offers excellent thermal stability and is commonly used in the manufacturing of high-efficiency PV cells.

The polycrystalline silicon base material is relatively low-cost and exhibits high mechanical strength and stability, widely used in the PV field.

The copper base material provides good conductive performance and thermal conductivity, suitable for applications requiring rapid electrical conduction.

The nickel base material offers superior corrosion resistance and mechanical strength, ideal for long-term electrode manufacturing.

The copper-nickel alloy base material combines the conductive performance of copper with the corrosion resistance of nickel, suitable for high-demand electrical equipment.

The nickel-iron alloy base material is magnetic and corrosion-resistant, often used in electromagnetic device manufacturing.

The iron-aluminum alloy base material is lightweight, heat-resistant, and corrosion-resistant, suitable for aerospace and high-temperature electrode applications.

The aluminum alloy base material is lightweight with good thermal conductivity, widely used in PV cell frames and electrical conductors.

S102. Desired polymer layer 2 is prepared on the mold 1 according to a preset process parameter to serve as the transfer substrate.

By directly preparing the polymer layer 2 with a micron- or nano-scale trench on the mold as the transfer substrate, this step simplifies the production process, reduces costs, and improves efficiency.

According to an embodiment of the present disclosure, preferably, the step S102 that the desired polymer layer 2 is prepared on the mold 1 according to a preset process parameter to serve as the transfer substrate is performed as follows.

15-85 μm thick polymer layer 2 with trench 3 is prepared on the mold 1. The polymer layer is dried at 100-180° C. and demolded from a side of the mold 1, and a desired polymer layer 2 with a micron- or nano-scale electrode pattern is obtained as the transfer substrate.

According to an embodiment of the present disclosure, preferably, in the step S102, the polymer layer 2 has a thickness of 15-50 μm. More preferably, the polymer layer has a thickness of 20-30 μm.

Based on the above description, the present disclosure achieves the following technical effects.

In the embodiment of the present disclosure, the mold is directly used to prepare the polymer layer and transfer the electrode grid lines, and the preparation method includes the following steps. S101. A preset mold complementary in terms of shape to an electrode pattern to be embossed is provided. S102. A desired polymer layer is prepared on the mold according to a preset process parameter to serve as the transfer substrate. S2. Conductive paste is applied onto a formed side of the polymer layer to at least completely fill the trench in the formed side, and then excess conductive paste is removed from a surface of the polymer layer, ensuring that a surface of the trench and a surface of the conductive paste are coplanar. S3. A base material is provided, the side of the polymer layer applied with the conductive paste is aligned and bonded to the base material, and the conductive paste is transferred onto the base material through a transfer method with a preset process parameter, where the process parameter for transferring includes a pressure of 1-20 MPa, a temperature of 80-180° C., and a duration of 0.5-10 min. S4. The polymer layer is removed to retain the conductive paste on the base material. S5. The conductive paste is sintered onto the base material, electrode grid lines with a preset aspect ratio are formed. In this way, the present disclosure achieves the goal of obtaining the desired polymer layer and preparing the electrode grid lines. The present disclosure realizes technical effects such as reduced process time, simplified workflows, extended mold lifespan, and excellent flexibility and separation ease of the substrate film. The present disclosure further addresses the following problems in transfer technology. The flexibility of transfer substrate films fails to meet usage requirements. For instance, some substrate films may be too soft, causing deformation after subsequent conductive paste filling, while others may be too hard, making them brittle and unusable. Additionally, the substrates may fail to automatically separate from the base material, thereby affecting the grid line structure. Currently, when a polymer layer is used to produce high-resolution electrode grid lines through high-precision hot-embossing and transfer, the high aspect ratio and narrow grid line spacing necessitate repeated high-pressure embossing and film peeling. This process will damage the mold and shorten its service life.

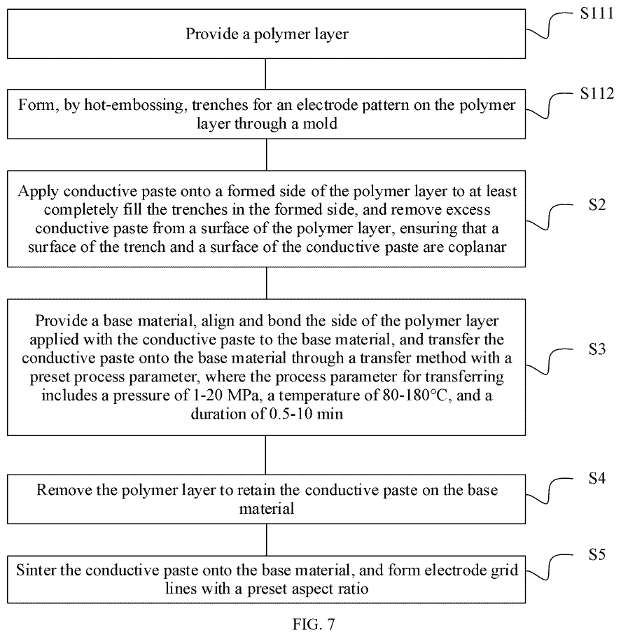

As shown in FIGS. 4 and 7, according to an embodiment of the present disclosure, preferably, the step S1 that the polymer layer is provided as a transfer substrate is further performed as follows.

S111. A polymer layer is provided.

According to an embodiment of the present disclosure, preferably, the step S111 that the polymer layer is provided is performed as follows.

A polymer layer with a thickness of 15-85 μm is prepared through an electrospinning method or a flatbed coating method.

Specifically, electrospinning is a technique that uses electrostatic forces to stretch polymer solutions into nano- or micron-scale fibers for preparing polymer films. The polymer layer prepared by the aforementioned method meets performance requirements.

When flatbed coating is used, the process is well-known to those skilled in the art.

Hot-embossing is employed to form the desired electrode pattern, improving precision and feasibility.

According to an embodiment of the present disclosure, preferably, in step S112, a trench of an electrode pattern is formed by hot-embossing on the polymer layer through a mold. This step is performed as follows.

The prepared polymer layer is placed on the mold and hot-embossed by a precision hot-embossing machine at 100-180° C., thereby forming a micron- or nano-scale trench structure on a surface of the polymer layer.

The hot-embossing machine ensures precision in the PVP transfer coating after hot-embossing, enabling rational design of grid line dimensions and shapes to reduce ohmic losses.

According to an embodiment of the present disclosure, preferably, in the step S1, the polymer layer 2 is prepared by an electrospinning method or a flatbed coating method.

Specifically, electrospinning is a technique that uses electrostatic forces to stretch polymer solutions into nano- or micron-scale fibers for preparing polymer films.

The polymer layer (15-85 μm thick) prepared through the electrospinning or flatbed coating method exhibits excellent performance and compatibility.

When flatbed coating is used, the process is well-known to those skilled in the art.

Based on the above description, the present disclosure achieves the following technical effects.

In the embodiment of the present disclosure, a hot-embossing method is adopted, and the preparation method includes the following steps. S111. A polymer layer is provided. S112. A trench of an electrode pattern is formed by hot-embossing on the polymer layer through a mold. S2. Conductive paste is applied onto a formed side of the polymer layer to at least completely fill the trench in the formed side, and excess conductive paste is removed from a surface of the polymer layer, ensuring that a surface of the trench and a surface of the conductive paste are coplanar. S3. A base material is provided, the side of the polymer layer applied with the conductive paste is aligned and bonded to the base material, and the conductive paste is transferred onto the base material through a transfer method with a preset process parameter, where the process parameter for transferring includes a pressure of 1-20 MPa, a temperature of 80-180° C., and a duration of 0.5-10 min. S4. The polymer layer is removed to retain the conductive paste on the base material. S5. The conductive paste is sintered onto the base material, and electrode grid lines with a preset aspect ratio are formed. In this way, the present disclosure achieves the goal of improving adhesion of the silver paste. The present disclosure achieves the technical effects of ensuring that the silver paste and the silicon wafer are securely bonded, improving the precision and stability of the electrode pattern, reducing production costs, and improving production efficiency. The present disclosure further addresses problems in the screen printing technology. That is, the precision of screen printing technology is constrained by screen mesh aperture and printing pressure, making it hard to achieve ultra-fine patterns and high-resolution printing. Generally, the width of silver paste lines is at least tens of micrometers. Besides, the screen printing process will generate a certain amount of waste, thereby leading to material losses. Screens have limited lifespans and are costly, resulting in high overall expenses. Furthermore, the relatively slow speed of screen printing cannot meet large-scale production demands, thereby impacting production efficiency.

As shown in FIG. 9, according to an embodiment of the present disclosure, preferably, a protrusion of the mold 1 is complementary to the trench 3 in shape.

The protrusion of the mold 1 is in the shape of one of an isosceles triangle, an isosceles trapezoid, an ellipse, a hexagon, a right-angle trapezoid, or a rectangle. The dimension and shape of the protrusion correspond to those of the electrode grid line. In practice, the dimension and shape of the transferred electrode grid line are controlled to reduce ohmic losses of the transferred electrode grid line. A longitudinal shape of the protrusion includes but is not limited to one of a triangle, a trapezoid, a rectangle, a diamond, a semicircle, and a polygon. In this embodiment, the longitudinal section of the protrusion is preferably in the shape of a triangle or a trapezoid. The triangular or trapezoidal design of the longitudinal section helps alter light incidence and refraction paths, facilitating light trapping and guidance. This design can reduce reflective losses of light, enabling more light absorption by a semiconductor material and conversion into electrical energy, thereby improving photoelectric conversion efficiency.

The complementary shapes of the protrusion of the mold and the trench ensure precise alignment and embossing effects during mold processing, achieving high-precision transfer and enhancing final electrode grid line quality.

Specifically, the shape of the mold may be selected from the following geometrical configurations.

Isosceles triangles: Suitable for scenarios requiring concentrated force transmission, producing sharp and well-defined edges for the electrode grid line.

Isosceles trapezoids: Wider bases and narrower tops enable gradual width transitions in electrode grid lines, ensuring uniform paste filling during the transfer process.

Ellipses: Smooth edge transitions suit electrodes requiring uniform current distribution, minimizing resistance and localized stress.

Hexagons: Stable structures with uniform density distribution enhance transfer precision and stability of electrode grid lines.

Right-angle trapezoids: Ideal for PV electrode grid lines with uniform widths and clean edges, ensuring precise current distribution.

Rectangles: Classic designs for standardized electrode grid lines, maximizing contact area to improve current conduction.

According to an embodiment of the present disclosure, preferably, a shape of the mold features an aspect ratio of 1 to 3.

The aspect ratio of 1 to 3 offered by the shape of the mold effectively adjusts the relationship between the protrusion height and width of the mold to optimize the transfer effect of the electrode grid line.

Specifically, when the aspect ratio is 1, the height and width of the mold are equal, suitable for electrode structures requiring flat grid lines with uniform thickness and width. This ensures good conductive performance of the electrode and uniform distribution of the conductive paste 4 during transfer.

In this embodiment, preferably, an aspect ratio close to 2 provides moderate thickness and width, enhancing the mechanical strength of the electrode while ensuring certain height of grid line, thereby maintaining a fine structure. The design balances resistance, strength, and process difficulty, making it suitable for conventional PV electrode manufacturing.

When the aspect ratio is 3, the height of the grid line significantly exceeds its width, making it suitable for finer, narrower electrode designs. This effectively reduces resistance and increases current density. However, it demands higher mold precision during manufacturing to ensure complete filling of the conductive paste 4 in the narrow trench.

Thus, the flexible setting of the aspect ratio range allows adjustment of the geometrical shape of the electrode grid line based on different PV cell design requirements, achieving optimal balance among conductive performance, mechanical strength, and production process.

According to an embodiment of the present disclosure, preferably, a surface of the mold is coated with a self-assembled monolayer (SAM).

Coating the surface of the mold with the SAM further enhances pattern fidelity and peelability of the polymer layer while extending the service life of the mold.

Of course, the primary purpose of the SAM coated on the surface of the mold is to improve the surface properties of the mold, including but not limited to the following:

The SAM can reduce adhesion. The SAM minimizes surface adhesion, facilitating easier release of plastics or other materials during molding or calendaring, thereby improving production efficiency.

The SAM can control surface energy. The SAM adjusts the hydrophilicity/hydrophobicity of the surface of the mold, enhancing anti-adhesion performance and influencing material wettability to optimize flow and molding. In the present disclosure, the SAM increases the hydrophobicity of the mold.

The SAM can enhance corrosion resistance. The SAM improves the mold surface's resistance to corrosion, prolonging its lifespan.

According to an embodiment of the present disclosure, preferably, the SAM includes one of a silane compound, a siloxane compound, or a perfluorinated compound.

Specifically, the silane compound can be octadecyltrichlorosilane (OTS).

The siloxane compound can be octamethylcyclotetrasiloxane (OMCTS) and octamethyl-disiloxane (OMDS), which can form a hydrophobic organosilicon protective layer on a crystalline silicon surface.

The perfluorinated compound can be perfluorooctylthiol (PFOT), perfluorooctyltrichlorosilane (PFOTS), and 1H, 1H,2H,2H-perfluorodecyl-trichlorosilane.

These materials can form the SAM on the surface of the mold through immersion, vapor deposition, or chemical modification. Overall, the SAM coating improves the surface performance of the mold, enhances production efficiency, extends mold lifespan, and ensures embossing precision and quality.

S2. Conductive paste 4 is applied onto a formed side of the polymer layer 2 to at least completely fill the trench 3 in the formed side, and then excess conductive paste 4 is removed from a surface of the polymer layer 2, ensuring a surface of the trench 3 and a surface of the conductive paste 4 are coplanar.

This step achieves a good effect of coating the conductive paste 4, ensuring uniform distribution of the conductive paste on the polymer layer.

According to an embodiment of the present disclosure, preferably, the step S2 that the conductive paste 4 is applied onto a formed side of the polymer layer 2 to at least completely fill the trench 3 in the formed side, and then excess conductive paste 4 is removed from a surface of the polymer layer 2, ensuring a surface of the trench 3 and a surface of the conductive paste 4 are coplanar is performed as follows.

Using flatbed coating, the conductive paste is uniformly spread over the high-precision embossed polymer layer, ensuring tight filling of the conductive paste into the trench. Excess conductive paste is scraped off from the surface to ensure complete filling and uniform and deformation-free distribution of the conductive paste.

It should be noted that the PV conductive paste primarily includes a binder (e.g., phenolic resin, epoxy resin, etc.) to stabilize bonds between conductive particles and between particles and the silicon wafer.

S3. Base material 5 is provided, a side of the polymer layer 2 applied with the conductive paste 4 is aligned and bonded to the base material 5, and the conductive paste 4 is transferred onto the base material 5 through a transfer method with a preset process parameter, where the process parameter for transferring includes a pressure of 1-20 MPa, a temperature of 80-180° C., and a duration of 0.5-10 min.

According to an embodiment of the present disclosure, preferably, in the step S3, the side of the polymer layer 2 applied with the conductive paste 4 is aligned and bonded to the base material 5 as follows.

At a preset temperature, uniform-codirectional pressure is applied to make the conductive paste 4 tightly bonded to a surface of the base material 5 while the conductive paste 4 is dried. Within the temperature and the pressure, the conductive paste 4 transferred onto the base material 5 retains a macroscopic morphology unchanged. The base material 5 is selected from one of a crystalline silicon wafer base material, a glass base material, a metal base material, or a polymer base material.

Uniform-codirectional pressure and heat are applied to the non-coated side of the polymer layer. Due to the adhesion between the conductive paste and the silicon wafer, the conductive paste is transferred and tightly bonded to the silicon wafer, ensuring a good transfer effect and ensuring structural stability of the conductive paste.

S4. The polymer layer 2 is removed, such that the conductive paste transferred is retained on the base material 5.

According to an embodiment of the present disclosure, preferably, the step S4 that the polymer layer 2 is removed, such that the conductive paste 4 is retained on the base material 5 is performed as follows.

The silicon wafer after transferring is immersed into a 25-75° C. aqueous solution, such that the polymer layer is dissolved and separated, leaving a successfully transferred conductive paste pattern and forming a basic structure of electrode grid line 6.

This step achieves desired dissolution and separation of the polymer layer, achieving complete retention of the conductive paste pattern on the silicon wafer.

It should be noted that the dissolution and separation is performed as follows. The silicon wafer is held by an electric suction cup on its backside, suspended, and immersed vertically/horizontally in water. The aqueous solution is agitated or the silicon wafer is shaken, such that the polymer layer is dissolved and separated.

The dissolution method of the polymer layer includes, but is not limited to, low-frequency ultrasonic oscillation, magnetic stirring, mechanical vibration, and static immersion.

Of course, the water solubility of the PVP can be modified by adjustment in its molecular weight or blending modification for rapid dissolution in water.

S5. The conductive paste 4 is sintered onto the base material 5, and electrode grid lines 6 with a preset aspect ratio are formed.

According to an embodiment of the present disclosure, preferably, the step S5 that the conductive paste 4 is sintered on the base material 5, and electrode grid lines 6 with a preset aspect ratio are formed is performed as follows.

After the conductive paste 4 is transferred, the silicon wafer is placed in a high-temperature furnace, and the conductive paste 4 is sintered at 200-800° C., ensuring that the conductive paste is completely sintered and tightly bonded to the silicon wafer, thereby forming the high-precision electrode grid lines 6 with a preset aspect ratio.

After high-temperature sintering, the conductive paste forms the conductive paste electrode grid lines 6 with a desired depth and width. Preferably, the conductive paste electrode grid line is 10 μm deep and 5 μm wide.

According to an embodiment of the present disclosure, preferably, the conductive paste 4 is selected from one of silver paste, aluminum paste, copper paste, chromium paste, tin paste, indium paste, nickel paste, titanium paste, or tantalum paste; the silver paste further includes of pure silver particles, copper or nickel particles coated with silver. It can be understood that all these materials exhibit excellent conductive performance, offering a large number of materials available for flexible use, thereby enhancing market competitiveness. Most preferably, in the present disclosure, the conductive paste 4 is silver paste.

According to an embodiment of the present disclosure, preferably, the polymer layer 2 has a glass transition temperature of 60-120° C., and is made of a water-soluble polymer material.

According to an embodiment of the present disclosure, preferably, the water-soluble polymer material includes one of PVP, polyethylene glycol (PEG), polyvinyl alcohol (PVA), sodium polyacrylate (PAAS), polyvinyl alcohol-polyacrylic acid (PVA-PAA), or polyvinyl alcohol-polyacrylonitrile (PVA-PAN).

The PVA has an average polymerization degree of 1,700 and an alcoholysis degree of 88-92%. The PVA includes ordinary PVA and modified PVA. The modified PVA is carboxyl-modified PVA with a carboxyl modification degree of 2-8%. It should be noted that these materials exhibit excellent solubility and biocompatibility, fulfilling the requirements of the present disclosure. In the present disclosure, more preferably, the water-soluble polymer material is PVP. PVP has excellent water solubility, and PVP with different polymerization degrees can also dissolve in various organic solvents such as ethanol and acetone. The PVP can form a uniform and transparent film with good flexibility and adhesion. PVP is non-toxic, non-irritating, and biocompatible. PVP exhibits thermal stability during processing, making it suitable for various thermal processing techniques.

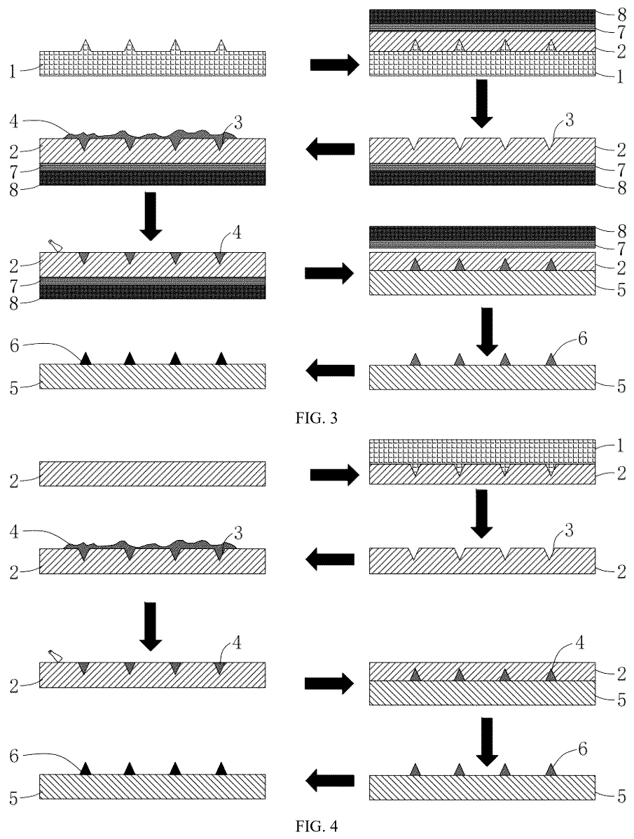

As shown in FIG. 3, according to an embodiment of the present disclosure, preferably, in the step S102, bonding layer 7 is provided at a side of the polymer layer 2 away from the mold 1, and substrate 8 is provided at a side of the bonding layer 7 away from the polymer layer 2. It can be understood that the composite structure of the bonding layer 7 and the substrate 8 enhances the stability, adhesion, and other physical properties of the composite material, while facilitating the separation of the polymer layer from the mold and its protection. Preferably, the bonding layer 7 is a thermosensitive release adhesive, which separates effectively under heat, enabling easy separation from the polymer layer.

According to an embodiment of the present disclosure, preferably, the substrate 8 is made of one of polyimide (PI), polyethylene terephthalate (PET), polyamide (PA), or polycarbonate (PC). It can be understood that the substrate provides mechanical support to the entire structure and withstands stress and deformation during processing. The substrate imparts specific stiffness, strength, and durability to the material. The availability of multiple substrate materials allows flexible selection and ease of use, improving practicality.

According to an embodiment of the present disclosure, preferably, in the step S3, during transferring with the preset process parameter, the bonding layer 7 and the substrate 8 are separated from the polymer layer 2. It can be understood that during hot-embossing, the thermosensitive release adhesive loses its adhesion under high temperatures. After transfer, the thermosensitive release adhesive and the substrate automatically separate from the polymer layer, achieving effective separation and ensuring a smooth process. The thermosensitive release adhesive undergoes an interfacial failure upon heating, i.e. exhibits significantly reduced adhesion to the base material under heat, enabling easy separation.

Through the structural design of the mold, the present disclosure can obtain the polymer layer with a micron-scale trench, thereby controlling the dimension and shape of the electrode grid line and reducing its ohmic losses. The triangular prism-shaped conductive paste grid line exhibits higher electrical conduction efficiency than a rectangular prism-shaped one, and light incident on the triangular side is more likely to refract into the cell panel for efficient utilization. PVP, as an environmentally friendly biodegradable material, poses minimal environmental harm. The room-temperature water solubility of the PVP polymer layer significantly reduces demolding costs. The method is simple, cost-effective, and employs eco-friendly materials and equipment.

Through electrospinning or coating, and transfer processes, the present disclosure precisely controls the dimension and shape of the transferred electrode grid line, reducing its ohmic losses. The triangular prism-shaped conductive paste grid line exhibits higher electrical conduction efficiency than a rectangular prism-shaped one, and light incident on the triangular side is more likely to refract into the cell panel for efficient utilization. PVP, as an environmentally friendly biodegradable material, poses minimal environmental harm. The room-temperature water solubility of the PVP coating significantly reduces demolding costs. The method is simple, cost-effective, and employs eco-friendly materials and equipment.

Furthermore, the present disclosure has the following beneficial effects:
1. The present disclosure improves the adhesion of the transferred conductive paste. By using PVP as an ideal carrier, the present disclosure achieves stronger adhesion between the conductive paste and the base material. The water solubility and biocompatibility of the PVP coating ensure that the conductive paste fills the trench tightly during transfer, securing firm bonding with the base material.

Specifically, the present disclosure selects an appropriate carrier material. PVP, a water-soluble, biocompatible, film-forming polymer, exhibits excellent adhesion, serving as an ideal carrier for transferring the conductive paste and ensuring secure bonding with the base material.
2. The present disclosure enhances the precision and stability of the electrode pattern. By preparing the PVP film with a micron- or nano-scale electrode pattern through electrospinning, the present disclosure achieves high-precision and stable electrode patterns, improving the performance and efficiency of the PV cell.
3. The present disclosure simplifies the production process. The present disclosure employs flatbed coating to coat the conductive paste onto the PVP film and transfers it to the base material. Thus, the present disclosure simplifies the production process, reduces the costs and time, and improves the efficiency.

Specifically, through flatbed coating, the conductive paste is applied, and then transferred to the silicon wafer. The PVP film is dissolved and separated in water at a suitable temperature, ultimately forming a 10 μm deep, 5 μm wide micron-scale electrode grid line after sintering, achieving successful transfer and sintering of the conductive paste.

Based on the above description, the present disclosure achieves the following technical effects.

In the embodiment of the present disclosure, the electrode grid lines are prepared by a transfer means, and the preparation method includes the following steps. S1. A polymer layer is provided as a transfer substrate. S2. Conductive paste is applied onto a formed side of the polymer layer to at least completely fill a trench in the formed side, and excess conductive paste is removed from a surface of the polymer layer, ensuring that a surface of the trench and a surface of the conductive paste are coplanar. S3. A base material is provided, the side of the polymer layer applied with the conductive paste is aligned and bonded to the base material, and the conductive paste is transferred onto the base material through a transfer method with a preset process parameter, where the process parameter for transferring includes a pressure of 1-20 MPa, a temperature of 80-180° C., and a duration of 0.5-10 min. S4. The polymer layer is removed to retain the conductive paste on the base material. S5. The conductive paste is sintered onto the base material, and electrode grid lines with a preset aspect ratio are formed. In this way, the present disclosure achieves the goal of preparing the electrode grid lines. The present disclosure realizes technical effects such as reduced process time, simplified workflows, and excellent flexibility and separation ease of the substrate film. The present disclosure further addresses the following problems in transfer technology. The flexibility of transfer substrate films fails to meet usage requirements. For instance, some substrate films may be too soft, causing deformation after subsequent conductive paste filling, while others may be too hard, making them brittle and unusable. Additionally, the substrates may fail to automatically separate from the base material, thereby affecting the grid line structure.

Compared with the screen printing technology, the conductive paste transfer technology further has the following advantages.
1. Higher resolution. The conductive paste transfer technology typically achieves higher resolution, enabling precise transfer of the conductive paste at a smaller scale to form a finer patterns and line.
2. More stable product quality. The conductive paste transfer technology under controlled conditions ensures more stable and consistent product quality, avoiding problems like uneven ink flow in screen printing.
3. Higher production efficiency. Generally, the conductive paste transfer technology can be automated, improving production efficiency, reducing manual labor and saving time and costs.
4. Broader applicability. The conductive paste transfer technology can be applied to various substrates and materials, including flexible substrates and non-flat surfaces.
5. Enhanced durability. The conductive paste transfer technology usually can provide better adhesion and durability, ensuring long-lasting and stable patterns resistant to environmental factors.

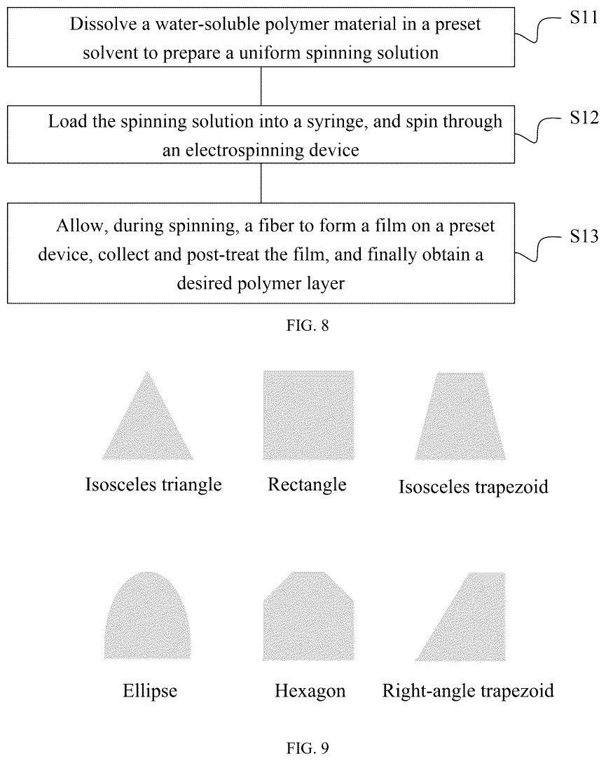

As shown in FIG. 8, the present disclosure further relates to a polymer layer preparation method, including the following steps.

S11. A water-soluble polymer material is dissolved in a preset solvent to prepare a uniform spinning solution.

This step enables the preparation of a uniform spinning solution through solution formulation.

According to an embodiment of the present disclosure, preferably, the step S11 that PVP is dissolved in the preset solvent to prepare the uniform spinning solution is performed as follows.

PVP and tetrabutyl titanate are dissolved in a mixed solvent of ethanol and acetic acid to prepare a precursor solution including 3-5 wt % PVP and 18-22 wt % tetrabutyl titanate.

According to an embodiment of the present disclosure, more preferably, PVP and tetrabutyl titanate are dissolved in a mixed solvent of ethanol and acetic acid to prepare a precursor solution including 4 wt % PVP and 20 wt % tetrabutyl titanate.

According to an embodiment of the present disclosure, preferably, the step S11 that the water-soluble polymer material is dissolved in the preset solvent to prepare the uniform spinning solution is further performed as follows.

PVP and diphenylalanine are slowly added into a mixed solvent of methanol and N,N-methylacetamide under stirring, and the stirring continues until the PVP and diphenylalanine are fully dissolved to obtain a transparent polymer solution.

Specifically, to obtain a suitable polymer layer, a uniform spinning solution must first be prepared. The key of this process lies in selecting appropriate solvent and precursor to ensure suitable viscosity and uniformity, thereby facilitating stable fiber formation through electrospinning.

The present disclosure provides multiple solution preparation schemes for flexible selection based on practical needs.

S12. The spinning solution is loaded into a syringe, and spinning is performed through an electrospinning device.

According to an embodiment of the present disclosure, preferably, the step S12 that the spinning solution is loaded into a syringe, and spinning is performed through an electrospinning device is performed as follows.

The prepared spinning solution is loaded into the syringe with a preset inner diameter, and electrospinning is performed with a preset working voltage.

During spinning, temperature and humidity are controlled to prevent fiber breakage or over-stretching, ensuring fiber stability, uniform thickness, and morphological consistency.

Of course, specific parameter settings are based on practical requirements and are not limited in the present disclosure.

S13. During spinning, a fiber forms a film on a preset device, the film is collected and post-treated, and finally a desired polymer layer is obtained. The preset device includes, but is not limited to, a mold or collection device.

According to an embodiment of the present disclosure, preferably, the step S13 that during spinning, a fiber forms a film on a preset device, the film is collected and post-treated, and finally a desired polymer layer is obtained is performed as follows.

The polymer layer formed by spinning deposits uniformly on a collection device, and a corresponding pretreatment step is performed based on an intended use of the fiber film.

Specifically, during spinning, the fiber forms a film on the collection device, and the fiber film is collected to obtain a PVP fiber film for post-treatment.

The PVP fiber film for post-treatment is modified synchronously with silicone oil.

The synchronously modified PVP fiber film is put into a programmed heating device, and a target temperature is achieved according to a preset heating curve and held for a preset duration to obtain a final PVP fiber film desired.

Of course, the polymer layer formed by spinning needs to uniformly deposit on the collection device or mold. The post-treatment step may vary depending on the final use of the polymer layer.

Through the above steps, a suitable polymer layer is prepared. The molecular structure of the polymer layer is as follows:

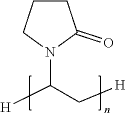

Those skilled in the art should recognize the aforementioned molecular structure.

The polymer layer prepared by the polymer layer preparation method of the present disclosure method exhibits certain flexibility (not too brittle) and avoids excessive softness of the substrate film to prevent deformation after conductive paste filling. Additionally, the polymer layer can subsequently dissolve in water for automatic separation from the silicon wafer without affecting the retained conductive paste.

The polymer layer has a glass transition temperature of 60-120° C., ensuring that PVP retains its shape without rebound after hot-embossing.

Based on the above description, the present disclosure achieves the following technical effects.

In the embodiment of the present disclosure, the polymer layer is prepared by electrospinning as follows. S11. A water-soluble polymer material is dissolved in a preset solvent to prepare a uniform spinning solution. S12. The spinning solution is loaded into a syringe, and spinning is performed through an electrospinning device. S13. During spinning, a fiber forms a film on a preset device, the film is collected and post-treated, and finally a desired polymer layer is obtained. The present disclosure realizes technical effects of excellent flexibility and separation ease in the substrate film. The present disclosure further addresses the following problems in transfer technology. That is, the flexibility of transfer substrate films fails to meet usage requirements. For instance, some substrate films may be too soft, causing deformation after subsequent conductive paste filling, while others may be too hard, making them brittle and unusable. Additionally, the substrates may fail to automatically separate from the base material, thereby affecting the grid line structure.

The polymer layer directly prepared on the mold by electrospinning replicates the trench depth with high precision while avoiding repeated embossing, thereby extending mold lifespan.

Specifically, the method of preparing a polymer layer on a mold is further described below according to embodiments.

### Embodiment 1

I. Solution preparation is performed. PVP and tetrabutyl titanate are dissolved in a mixed solvent of ethanol and acetic acid to prepare a precursor solution including 4 wt % PVP and 20 wt % tetrabutyl titanate.

II. A mold is provided and electrospinning is performed on the mold according to the following parameters: a working voltage of 1.8 kV/cm, an inner diameter of 0.43 mm in a syringe, a flow rate of 0.5 mL/h for the spinning solution, a temperature controlled at 25° C., and a humidity controlled at 45%. Through the spinning, a 50 μm thick polymer layer with an electrode pattern is directly formed on the mold.

III. Conductive paste coating and transfer are performed. The conductive paste is uniformly coated on a surface of a PVP film through a flatbed coating method. Excess conductive paste is scraped off, and the conductive paste is subsequently transferred to a surface of a silicon wafer.

IV. PVP removal is performed. The PVP is cleaned in 60° C. water for 3 min, such that the polymer layer is completely dissolved and separated.

V. Conductive paste sintering is performed. After the transfer, the silicon wafer is sintered at 700° C. for half a minute to form conductive paste electrode grid lines.

In this embodiment, test results of the electrode grid line transfer method are as follows. The conductive paste electrode grid line exhibits a depth of 10 μm and a width of 5 μm, demonstrates tight adhesion to the silicon wafer with excellent conductive performance, and is suitable for applications in efficient PV cells.

### Embodiment 2

Embodiment 2 differs from Embodiment 1 in the following aspects. I. Solution preparation is performed. 4 wt % PVP and 10 wt % diphenylalanine are dissolved in a mixed solvent of methanol and N,N-methylacetamide to form a uniform polymer solution.

II. A mold is provided, and electrospinning is performed under identical electrospinning conditions to form a 65 μm thick polymer layer.

III. Conductive paste coating and transfer is performed. The same method is adopted for coating and transferring the conductive paste.

IV. PVP removal is performed. PVP is cleaned in 70° C. water for 7 min to dissolve and remove the PVP.

V. Conductive paste sintering is performed at 800° C. for half a minute.

In this embodiment, test results of the electrode grid line transfer method are as follows. The conductive paste electrode grid line exhibits a depth of 9 μm and a width of 6 μm, with satisfactory conductive paste transfer quality.

### Embodiment 3

Embodiment 3 differs from Embodiment 1 in the following aspects. I. Solution preparation is performed. The same PVP and tetrabutyl titanate solution as in Embodiment 1 are used.

II. A mold is provided to perform electrospinning is performed. By increasing a flow rate of a spinning solution to 1 mL/h, an 85 μm thick polymer layer is formed.

III. Conductive paste coating and transfer is performed. The same method is adopted for coating and transferring the conductive paste.

IV. PVP removal is performed. PVP is cleaned in 55° C. water for 8 min to dissolve and remove the PVP.

V. Conductive paste sintering is performed at 700° C. for 1 min.

In this embodiment, test results of the electrode grid line transfer method are as follows. The conductive paste electrode grid line demonstrates a depth of 12 μm and a width of 7 μm, with comparable conductive performance to the previous embodiment. However, partial uneven transfer of the conductive paste is observed due to the thick polymer layer, resulting in a slight decline in conductive performance.

### Embodiment 4

Embodiment 4 differs from Embodiment 1 in adopting a traditional PVP coating process.

I. PVP coating is performed. The traditional coating method is adopted to directly spread a PVP solution onto the mold, achieving a 25 μm thick layer.

In this embodiment, test results of the electrode grid line transfer method are as follows. The conductive paste electrode grid line exhibits a depth of 12 μm and a width of 6 μm, with comparable conductive performance to the previous embodiment.

### Embodiment 5

Embodiment 5 differs from Embodiment 1 in using PEG as the substrate material.

In this embodiment, test results of the electrode grid line transfer method are as follows. The conductive paste electrode grid line exhibits a depth of 11 μm and a width of 6 μm, with comparable conductive performance to the previous embodiment.

### Embodiment 6

Embodiment 6 differs from Embodiment 4 in using PVA as the substrate material and coating it to the mold via flatbed coating.

In this embodiment, test results of the electrode grid line transfer method are as follows. The conductive paste electrode grid line exhibits a depth of 11 μm and a width of 6 μm, with comparable conductive performance to the previous embodiment.

An analysis of the above test results indicates that:

Embodiments 1 to 6 all achieve high-precision conductive paste electrode grid lines with excellent conductive performance and low contact resistance. Among them, Embodiment 1 exhibits optimal performance, improving photoelectric conversion efficiency while reducing industrial production costs.

Specifically, the method of preparing a polymer layer by hot-embossing on a mold in the present disclosure is further described below according to other embodiments.

### Embodiment 7

I. Solution preparation is performed. PVP and tetrabutyl titanate are dissolved in a mixed solvent of ethanol and acetic acid to prepare a precursor solution including 4 wt % PVP and 20 wt % tetrabutyl titanate.

II. Electrospinning is performed according to the following parameters: a working voltage of 1.8 kV/cm, an inner diameter of 0.43 mm in a syringe, a flow rate of 0.5 mL/h for the spinning solution, a temperature controlled at 25° C., and a humidity controlled at 45%. Through the spinning, a 50 μm thick PVP film is formed.

III. High-precision hot-embossing is performed. A precision hot-embossing machine is used to perform hot-embossing through the mold at 135° C., with a pressure of 20 MPa, thereby forming a micron- or nano-scale trench pattern on a fiber film surface.

IV. Silver paste coating and transfer is performed. Silver paste is uniformly applied onto the surface of the PVP film via flatbed coating, excess paste is scraped off, and the paste is transferred to a surface of a silicon wafer.

V. PVP removal is performed. The PVP is cleaned in 50° C. water for 5 min, such that the PVP film is completely dissolved and separated.

VI. Silver paste sintering is performed. After the transfer, the silicon wafer is sintered at 700° C. for 1 min to form silver paste electrode grid lines.

In this embodiment, test results of the silver line transfer method are as follows. The silver paste electrode grid line exhibits a depth of 10 μm and a width of 7 μm, demonstrates tight adhesion to the silicon wafer with excellent conductive performance, and is suitable for applications in efficient PV cells.

### Embodiment 8

Embodiment 8 differs from Embodiment 7 in the following aspects. I. Solution preparation is performed. The same PVP and tetrabutyl titanate solution as in Embodiment 1 are used.

II. Electrospinning is performed. By increasing a flow rate of a spinning solution to 1 mL/h, an 85 μm thick PVP film is formed.

III. High-precision hot-embossing is performed. at 125° C. and 25 MPa to form a micron-scale trench.

IV. Silver paste coating and transfer is performed. The same method is adopted for coating and transferring silver paste.

V. PVP removal is performed. PVP is cleaned in 55° C. water for 8 min to dissolve and remove the PVP.

VI. Silver paste sintering is performed at 700° C. for 1 min.

In this embodiment, test results of the Silver line transfer method are as follows. The conductive paste electrode grid line demonstrates a depth of 9 μm and a width of 7 μm, with comparable conductive performance to the previous embodiment. However, uneven thicknesses of the film after spinning are observed due to the thick PVP film, leading to partial incomplete transfer of the silver paste, thereby resulting in a slight decline in conductive performance.

### Embodiment 9

Embodiment 9 differs from Embodiment 7 in the following aspects. I. A PVA solution is prepared. 8 g of PVA powder is dissolved in 92 mL of distilled water to prepare an 8% PVA solution. The PVA solution is stirred at 80° C. for 1 hour until complete dissolution of the PVA yields a uniform solution.

II. An electrospinning device is set up. The PVA solution is loaded into a syringe with a 0.43 mm inner diameter. A high-voltage power supply is set to 15 kV. A collection plate maintains a 12 cm distance from a syringe needle.

III. A spinning process is performed. Under an electric field, the PVA solution is ejected from the syringe needle to form nanofibers deposited on the rotating collection plate. Spinning continues for 30 min until a uniform fibrous network film is formed.

IV. Drying and post-treatment is performed. The film is dried in a 40° C. oven for 12 h to remove moisture and stabilize the film.

In this embodiment, test results of the electrode grid line transfer method are as follows. The electrospun PVA film exhibits a nano-scale fibrous structure with fiber diameters of 150-300 nm and a porous morphology. The high porosity of the film renders it suitable for gas filtration and biomedical applications. The fiber film features a 20 MPa tensile strength and 50% elongation at break.

In this embodiment, test results of the electrode grid line transfer method are as follows. The conductive paste electrode grid line exhibits a depth of 8 μm and a width of 8 μm, demonstrates tight adhesion to the silicon wafer with excellent conductive performance, and is suitable for applications in efficient PV cells.

### Embodiment 10

Embodiment 10 differs from Embodiment 7 in adopting a traditional PVP coating process.

I. PVP coating is performed. The traditional coating method is adopted to directly spread a PVP solution onto a silicon wafer, achieving a 40 μm thick layer.

II. Hot-embossing is performed at 100° C. and 10 MPa to form an electrode trench.

III. Silver paste coating and transfer is performed. The same method is adopted for coating and transferring silver paste.

VI. PVP removal is performed. PVP is cleaned in 30° C. water for 6 min.

V. Silver paste sintering is performed at 700° C. for 1 min.

In this embodiment, test results of the electrode grid line transfer method are as follows. The silver paste electrode grid line exhibits a depth of 6 μm and a width of 10 μm. The PVP coating has good uniformity and the silver paste exhibits a desired filling effect, enabling a uniform width of the electrode line and desired conductive performance, meeting the requirements for high-precision PV cells.

### Comparative Example 1

Comparative Example 1 differs from Embodiment 7 in the following aspects. I. Solution preparation is performed. 4 wt % PVP and 10 wt % diphenylalanine are dissolved in a mixed solvent of methanol and N,N-methylacetamide to form a uniform polymer solution.

II. Electrospinning is performed under identical electrospinning conditions to form a 65 μm thick PVP film.

III. High-precision hot-embossing is performed at 70° C. and 15 MPa to form a micron-scale trench.

IV. Silver paste coating and transfer is performed. The same method is adopted for coating and transferring silver paste.

V. PVP removal is performed. PVP is cleaned in 60° C. water for 7 min to dissolve and remove the PVP.

VI. Silver paste sintering is performed at 800° C. for half a minute.

In this embodiment, test results of the electrode grid line transfer method are as follows. The silver paste electrode grid line exhibits a depth of 2 μm and a width of 6 μm, resulting in poor silver paste transfer quality.

An analysis of the above test results indicates that:
1. Embodiments 7 to 10 all successfully prepare high-precision silver paste electrode grid lines with excellent conductive performance, flexibility, water solubility, and adhesion strength. Embodiment 7 demonstrates the best performance.
2. Embodiment 7 and Comparative Example 1 reveal that insufficient hot-embossing temperature prevents complete compaction of the PVP film, leading to poorly defined silver paste electrode trenches and degraded conductive performance.

The present disclosure further relates to a PV cell, including electrode grid lines prepared according to the above method. The PV electrode grid lines prepared in this embodiment can be applied to PV cells. Its fundamental principles and resulting technical effects are consistent with those described in the aforementioned embodiment. For aspects not explicitly mentioned in this embodiment, please refer to the corresponding content in the preceding section.

The preferred implementations of the present disclosure are described above in detail with reference to the drawings, but the present disclosure is not limited to the specific details in the above implementations. Various equivalent variations can be made to the technical solutions of the present disclosure without departing from the technical ideas of the present disclosure, but such equivalent variations should fall within the protection scope of the present disclosure.

What is claimed is:

1. A preparation method of electrode grid lines, comprising the following steps:
S1: providing a polymer layer as a transfer substrate;
S2: applying conductive paste onto a formed side of the polymer layer to at least completely fill a trench in the formed side, and removing excess conductive paste from a surface of the polymer layer, ensuring that a surface of the trench and a surface of the conductive paste are coplanar;
S3: providing a base material, aligning and bonding the formed side of the polymer layer applied with the conductive paste to the base material, and transferring the conductive paste onto the base material through a transfer method with a preset process parameter, wherein the process parameter for transferring comprises a pressure of 1-20 MPa, a temperature of 80-180° C., and a duration of 0.5-10 min;
S4: removing the polymer layer to retain the conductive paste on the base material; and
S5: sintering the conductive paste onto the base material, and forming electrode grid lines with a preset aspect ratio.

2. The preparation method of the electrode grid lines according to claim 1, wherein the step S1: providing the polymer layer as a transfer substrate comprises the following steps:
S101: providing a preset mold complementary in terms of shape to an electrode pattern to be embossed; and
S102: preparing a desired polymer layer on the mold according to a preset process parameter to serve as the transfer substrate.

3. The preparation method of the electrode grid lines according to claim 2, wherein the step S102: preparing the desired polymer layer on the mold according to the preset process parameter to serve as the transfer substrate comprises:
preparing a 15-85 μm thick polymer layer with a trench on the mold, drying the polymer layer at 100-125° C., demolding from a side of the mold, and obtaining a desired polymer layer with a micron- or nano-scale electrode pattern as the transfer substrate.

4. The preparation method of the electrode grid lines according to claim 2, wherein in the step S102, the polymer layer has a thickness of 15-50 μm.

5. The preparation method of the electrode grid lines according to claim 1, wherein the step S1: providing the polymer layer as the transfer substrate further comprises the following steps:
S111: providing a polymer layer; and
S112: forming, by hot-embossing, the trench for an electrode pattern on the polymer layer through a mold.

6. The preparation method of the electrode grid lines according to claim 1, wherein the step S1 comprises: preparing the polymer layer by an electrospinning method or a flatbed coating method.

7. The preparation method of the electrode grid lines according to claim 1, wherein the step S1 comprises: preparing the polymer layer by an electrospinning method as follows:
S11: dissolving a water-soluble polymer material in a preset solvent to prepare a uniform spinning solution;
S12: loading the spinning solution into a syringe, and spinning through an electrospinning device; and
S13: allowing, during spinning, a fiber to form a film on a preset device, collecting and post-treating the film, and obtaining a desired polymer layer.

8. The preparation method of the electrode grid lines according to claim 7, wherein the step S11: dissolving the water-soluble polymer material in the preset solvent to prepare the uniform spinning solution comprises:
dissolving polyvinyl pyrrolidone (PVP) and tetrabutyl titanate in a mixed solvent of ethanol and acetic acid, and preparing a precursor solution comprising 3-5 wt % PVP and 18-22 wt % tetrabutyl titanate.

9. The preparation method of the electrode grid lines according to claim 7, wherein the step S11: dissolving the water-soluble polymer material in the preset solvent to prepare the uniform spinning solution comprises:
slowly adding PVP and diphenylalanine into a mixed solvent of methanol and N,N-methylacetamide under stirring, continuously stirring until the PVP and diphenylalanine are fully dissolved, and obtaining a transparent polymer solution.

10. The preparation method of the electrode grid lines according to claim 7, wherein the step S12: loading the spinning solution into the syringe, and spinning through the electrospinning device comprises:
loading the prepared spinning solution into the syringe with a preset inner diameter, and performing electrospinning with a preset working voltage.

11. The preparation method of the electrode grid lines according to claim 7, wherein the step S13: allowing, during spinning, the fiber to form the film on the preset device, collecting and post-treating the film, and obtaining the desired polymer layer comprises:
allowing a polymer layer formed by spinning to deposit uniformly on a collection device, and performing a corresponding pretreatment step based on an intended use of a fiber film.

12. The preparation method of the electrode grid lines according to claim 5, wherein the step S111: providing the polymer layer comprises:
preparing a polymer layer with a thickness of 35-85 μm through an electrospinning method or a flatbed coating method.

13. The preparation method of the electrode grid lines according to claim 5, wherein the step S112: forming, by hot-embossing, the trench for the electrode pattern on the polymer layer through the mold comprises:
placing the prepared polymer layer on the mold, and hot-embossing, by a precision hot-embossing machine, the polymer layer at 100-180° C., wherein a micron- or nano-scale trench structure is formed on a surface of the polymer layer.

14. The preparation method of the electrode grid lines according to claim 2, wherein the mold comprises one of a monocrystalline silicon base material, a polycrystalline silicon base material, a copper base material, a nickel base material, a copper-nickel alloy base material, a nickel-iron alloy base material, an iron-aluminum alloy base material, or an aluminum alloy base material.

15. The preparation method of the electrode grid lines according to claim 2, wherein a protrusion of the mold is complementary to the trench in shape; and
the mold is in the shape of one of an isosceles triangle, an isosceles trapezoid, an ellipse, a hexagon, a right-angle trapezoid, or a rectangle.

16. The preparation method of the electrode grid lines according to claim 2, wherein a shape of the mold features an aspect ratio of 1 to 3.

17. The preparation method of the electrode grid lines according to claim 2, wherein a surface of the mold is coated with a self-assembled monolayer (SAM).

18. The preparation method of the electrode grid lines according to claim 17, wherein the SAM comprises one of a silane compound, a siloxane compound, or a perfluorinated compound.

19. The preparation method of the electrode grid lines according to claim 1, wherein the step S2: applying the conductive paste onto the formed side of the polymer layer to at least completely fill the trench in the formed side, and removing the excess conductive paste from the surface of the polymer layer, ensuring that the surface of the trench and the surface of the conductive paste are coplanar comprises:
uniformly spreading, by a flatbed coating method, the conductive paste over the formed polymer layer, wherein the conductive paste completely fills the trench; and scraping off excess conductive paste to ensure complete filling and uniform and deformation-free distribution of the conductive paste.

20. The preparation method of the electrode grid lines according to claim 1, wherein in the step S3, the step of providing the base material, and aligning and bonding the formed side of the polymer layer applied with the conductive paste to the base material comprises:
tightly bonding, while drying the conductive paste, the conductive paste to a surface of the base material by applying uniform-codirectional pressure at a preset temperature; and remaining, within the temperature and the pressure, a macroscopic morphology of the conductive paste transferred onto the base material unchanged;
wherein the base material is selected from one of a crystalline silicon wafer base material, a glass base material, a perovskite base material, a metal base material, or a polymer base material.

21. The preparation method of the electrode grid lines according to claim 1, wherein the step S4: removing the polymer layer to retain the conductive paste on the base material comprises:
immersing a silicon wafer after transferring into a 25-75° C. aqueous solution, wherein the polymer layer is dissolved and separated, leaving a successfully transferred conductive paste pattern, and forming a basic structure of a photovoltaic (PV) electrode grid line.

22. The preparation method of the electrode grid lines according to claim 1, wherein the step S5: sintering the conductive paste onto the base material, and forming the electrode grid lines with the preset aspect ratio comprises:
placing a silicon wafer with the transferred conductive paste in a high-temperature furnace; sintering the conductive paste at 200-800° C., ensuring that the conductive paste is completely sintered and tightly bonded to the silicon wafer; and forming the electrode grid lines with a preset aspect ratio.

23. The preparation method of the electrode grid lines according to claim 1, wherein the conductive paste is selected from one of silver paste, aluminum paste, copper paste, chromium paste, tin paste, indium paste, nickel paste, titanium paste, or tantalum paste; the silver paste further comprises of pure silver particles, copper or nickel particles coated with silver.

24. The preparation method of the electrode grid lines according to claim 1, wherein the polymer layer has a glass transition temperature of 60-120° C., and is made of a water-soluble polymer material.

25. The preparation method of the electrode grid lines according to claim 24, wherein the water-soluble polymer material comprises one of PVP, polyethylene glycol (PEG), polyvinyl alcohol (PVA), sodium polyacrylate (PAAS), polyvinyl alcohol-polyacrylic acid (PVA-PAA), or polyvinyl alcohol-polyacrylonitrile (PVA-PAN); and
the PVA has an average polymerization degree of 1,700 and an alcoholysis degree of 88-92%; the PVA comprises ordinary PVA and modified PVA; and the modified PVA is carboxyl-modified PVA with a carboxyl modification degree of 2-8%.

26. The preparation method of the electrode grid lines according to claim 2, wherein the step S102 further comprises: providing a bonding layer at a side of the polymer layer away from the mold, and providing a substrate at a side of the bonding layer away from the polymer layer.

27. The preparation method of the electrode grid lines according to claim 26, wherein the substrate is made of one of polyimide (PI), polyethylene terephthalate (PET), polyamide (PA), or polycarbonate (PC).

28. The preparation method of the electrode grid lines according to claim 26, wherein the step S3 further comprises: separating, during transferring with the preset process parameter, the bonding layer and the substrate from the polymer layer.

29. A photovoltaic (PV) cell, comprising the electrode grid lines prepared by the preparation method according to claim 1.
